(19) United States
(12) Patent Application Publication
(10) Pub. No.: US 2020/0196478 A1
(43) Pub. Date: Jun. 18, 2020

(54) DATA STORAGE ENCLOSURE ACOUSTICS

(71) Applicant: Seagate Technology LLC, Cupertino, CA (US)

(72) Inventors: Kevin Lee Van Pelt, Longmont, CO (US); Lon Matthew Stevens, Longmont, CO (US)

(21) Appl. No.: 16/224,269

(22) Filed: Dec. 18, 2018

(51) Int. Cl. H05K 7/14; H05K 7/20; G11B 33/14

(52) U.S. Cl. CPC H05K 7/1488; G11B 33/142; H05K 7/20736; H05K 7/20145

(57) ABSTRACT

A system includes a drawer with a chassis. The chassis includes a data storage area and a cooling plenum with metal surfaces. The system also includes air movers positioned within the cooling plenum. An acoustic absorptive material covers at least a portion of the metal surfaces in the cooling plenum to absorb acoustic energy generated by the air-movers.

### SUMMARY

In certain embodiments, a system includes a drawer with a chassis. The chassis includes a data storage area and a cooling plenum with metal surfaces. The system also includes air movers positioned within the cooling plenum. An acoustic absorptive material covers at least a portion of the metal surfaces in the cooling plenum to absorb acoustic energy generated by the air-movers.

In certain embodiments, a system includes a drawer with a chassis. The chassis includes data storage areas and a cooling plenum positioned between the data storage areas. The cooling plenum includes metal surfaces. The system also includes fan modules positioned within the cooling plenum and that generate acoustic energy in opposite directions. An acoustic absorptive material covers at least a portion of the metal surfaces in the cooling plenum to reduce an amount of the acoustic energy generated by the fan modules from transporting to the data storage areas.

In certain embodiments, a method is disclosed for attenuating acoustic energy generated by fan modules positioned in a cooling plenum of a drawer of a data storage system. The method includes powering the fan modules to rotate blades around a rotational axis to generate acoustic energy, absorbing at least some of the acoustic energy via an acoustic absorptive material covering metal surfaces of the cooling plenum between the fan modules and data storage devices positioned within the drawer, and directing at least some of the acoustic energy to the data storage devices.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 shows a perspective view of a storage system, in accordance with certain embodiments of the present disclosure.

FIG. 2 shows a partially exploded, perspective view of a drawer, in accordance with certain embodiments of the present disclosure.

FIG. 3 shows a top view of the drawer of FIG. 2 with storage devices positioned therein, in accordance with certain embodiments of the present disclosure.

FIG. 4 shows a partially exploded, perspective view of a back end of the drawer of FIGS. 2 and 3, in accordance with certain embodiments of the present disclosure.

FIG. 5 shows a sectional side view of the drawer of FIGS. 2-4, in accordance with certain embodiments of the present disclosure.

FIG. 6 shows a sectional side view of a drawer, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope the appended claims.

### DETAILED DESCRIPTION

Data storage systems are used to store and process vast amounts of data. It can be challenging to keep the systems within a desired temperature range because of the amount of heat the systems typically generate during operation. Data storage systems can include cooling devices such as air movers (e.g., fans) that assist with maintaining the systems within the desired temperature range. However, air movers generate undesirable acoustical energy that may be transmitted throughout the system, which can affect performance of data storage devices housed within the system. Certain embodiments of the present disclosure feature arrangements of cooling devices and acoustically-absorptive material that reduce the amount of acoustic energy within a data storage system.

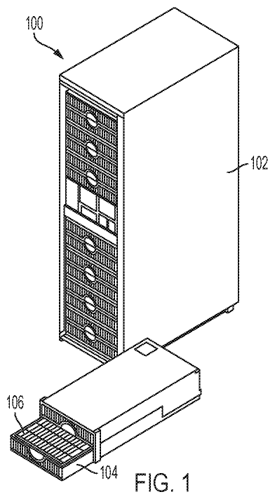

FIG. 1 shows a data storage system 100 including a rack 102 (e.g., a cabinet) with a plurality of drawers 104. Each drawer 104 can be configured as a sliding enclosure such that the drawer 104 can extend horizontally away from the rack 102 to expose a set of data storage devices 106 installed within the drawer 104. In certain embodiments, the drawer 104 does not slide into and out of the rack 102 such that the drawers 104 are separate enclosures within the rack 102.

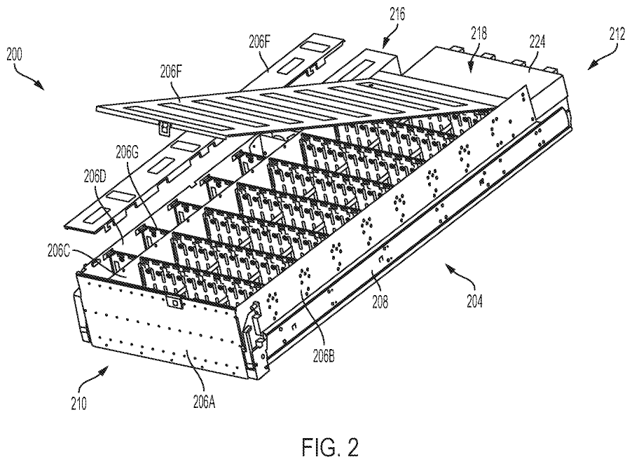

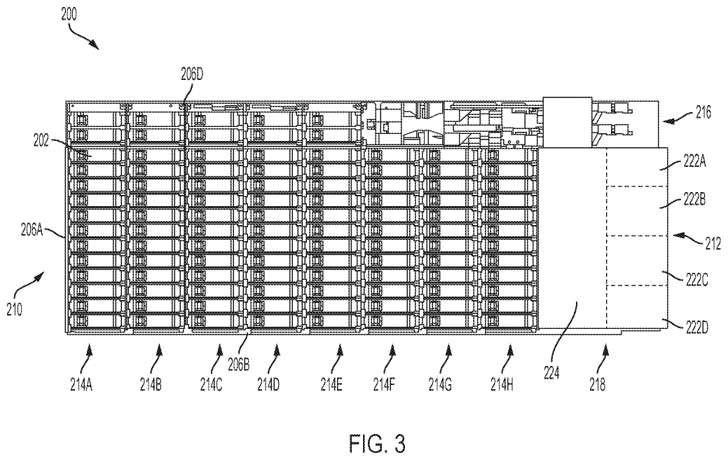

FIG. 2 shows a partially exploded view of a drawer 200, such as the drawer 104 in FIG. 1, which can be utilized in a data storage system such as the data storage system 100 of FIG. 1. FIG. 3 shows a top view of the drawer 200 with data storage devices 202 positioned within the drawer 200.

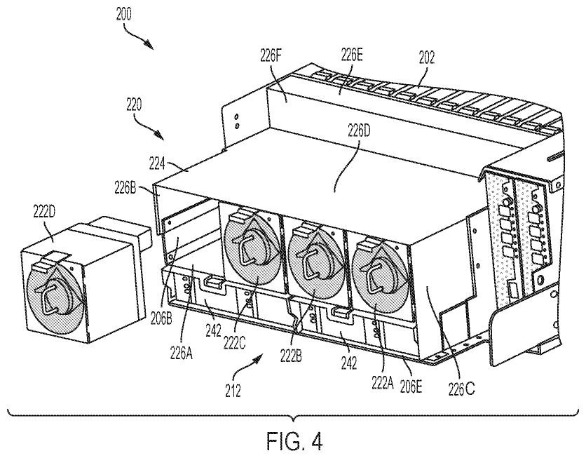

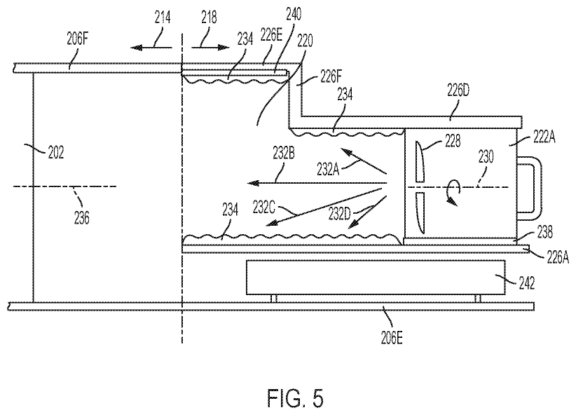

The drawer 200 includes a chassis 204 with a front side wall 206A, first side wall 206B, a second side wall 206C, a third side wall 206D, a bottom wall 206E (shown in FIGS. 4 and 5), multiple top covers 206F, and multiple laterally-extending interior walls 206G that extend between the various side walls. The walls of the chassis 204 may be referred to below as chassis walls to distinguish from walls of other parts of the drawer 200. The drawer 200 includes slides 208 coupled to the chassis 204 that enable the drawer 200 to move into and out of a rack, such as the rack 102 of FIG. 1.

The chassis 204 extends between a front end 210 and a back end 212 and forms an enclosure. When assembled, the chassis 204 houses and supports the data storage devices 202 (e.g., hard disc drives and/or solid state drives), electrical components (e.g., wiring and circuit boards), and cooling devices (e.g., air movers). For example, the chassis 204 can be split into one or more data storage areas 214A-H, electrical components areas 216, and cooling plenum areas 218.

FIG. 3 shows eight rows of separate data storage areas 214A-H extending between the first side wall 206A and the third side wall 206C. The first data storage area 214A near the front end 210 of the chassis 204 extends between the front side wall 206A and one of the interior walls 206G, and the rest of the data storage areas 214B-H extend between two of the interior walls 206G. Each data storage device 202 can be removably coupled between the front side wall 206A and one of interior walls 206G in the first data storage area 214A or between two of the interior walls 206G in the other data storage areas 214B-H. The chassis 204 is shown as including one electrical component area 216 where various electrical controllers, printed circuit boards, etc., are positioned. In other embodiments, the chassis could include multiple electrical component areas.

The chassis 204 is also shown as including one cooling plenum area 218 that extends from the back end 212 of the chassis 204 towards the front end 214 of the chassis 204. The cooling plenum area 218 includes a cooling plenum 220 with several cooling devices 222A-D (e.g., air-movers, fans) positioned within the cooling plenum 220. Air moved by the cooling devices 222A-D is directed through the cooling plenum 220 towards the data storage devices 202 in the data storage areas 214A-H. Although the cooling devices 222A-D are shown as being positioned within the cooling plenum 220, the cooling devices 222A-D can be positioned outside of the cooling plenum 220 such that air generated by the cooling devices 222A-D is directed through the cooling plenum 220. Further, the chassis 204 may include multiple cooling plenums. For example, each cooling device 222A-D may be associated with its own cooling plenum. In another example, two or more cooling devices may share a cooling plenum. In certain embodiments, the cooling plenum 220 does not include or otherwise house data storage devices 202.

The cooling plenum 220 can be formed, at least in part, by chassis walls and one or more separate cooling plenum components. For example, FIG. 4 shows one of the side walls 226B of the cooling plenum 220 formed by both the chassis first side wall 206B and a part of a cooling plenum frame 224, which is coupled to the chassis 204 at the back end 212 of the chassis 204. The cooling plenum frame 224 can be a separate component of the drawer 200 that is fastened to the chassis 204 to create the cooling plenum 220. For example, the cooling plenum frame 224 can be a single piece of sheet metal that is bent to form at least part (e.g., one or more walls) of the cooling plenum 220.

As shown in FIGS. 4 and 5, the cooling plenum 220 includes a bottom plenum wall 226A, a first side plenum wall 226B (FIG. 4), a second side plenum wall 226C (FIG. 4), a first top plenum wall 226D, a second top plenum wall 226E, and a back plenum wall 226F. Although not shown in the Figures, some of the chassis walls may form the plenum walls. For example, a single wall may form both the chassis side wall and plenum side wall (e.g., a single wall formed by one piece of sheet metal or formed by the same two pieces of sheet metal). The plenum walls and the chassis walls can be made of metal (e.g., aluminum, steel) in the form of sheets of metal.

The cooling devices 222A-D are fan modules with blades 228 (shown in FIG. 5) that rotate around a rotation axis 230. The fan modules 222A-D move air through the rest of the cooling plenum 220 (e.g., within the walls of the cooling plenum 220) towards the data storage devices 202 in the data storage areas 214A-H. The air serves to cool the data storage devices 202, which generate heat during their operation. As drawers are more densely packed with data storage devices, the drawers require more cooling to maintain desired operating temperatures for the data storage devices. One approach for addressing increased cooling needs is to increase the speed at which the fan modules' blades rotate.

However, rotating the blades 228 of the fan modules 222A-D generates acoustic energy (e.g., energy transmitted through air) and chassis vibration (e.g., energy transmitted through the chassis 204 itself)—both of which can affect the performance of the data storage devices 202. FIG. 5 includes four arrows 232A-D that each represent a different transmission direction of acoustic energy (as opposed to chassis vibration) generated by the fan module. When acoustic energy or chassis vibration is transmitted to the data storage devices 202 in the drawer 200, the data storage devices 202 vibrate, which affects the data storage devices' 202 ability to write data and read data. For data storage devices 202 that are hard disk drives, the vibration resulting from acoustic energy and chassis vibration makes it difficult for the read/write heads in the hard disk drives to settle on or follow a desired data track during data reading and data writing operations. In some situations, the acoustic energy generated by fan modules can have a greater impact on the performance of data storage devices 202 within the system compared to chassis vibration transmitted through the chassis to the data storage devices 202. Further, data storage devices 202 positioned closest to the fan modules (e.g., the data storage devices in the data storage area 214H of the chassis 204) are affected by acoustic energy more than the data storage devices 202 positioned in the other data storage areas 214A-G of the chassis 204.

As noted above, the walls of the cooling plenum 220 are made of metal, which reflects acoustic energy such that little to no acoustic energy is absorbed when acoustic energy is transmitted to and reflected off the metal surfaces of the plenum walls. As such, most of the acoustic energy generated by the fan modules 222A-D and transmitted from the cooling plenum 220 to the data storage areas 214A-H ultimately impacts one or more of the data storage devices 202—thus reducing performance of the data storage devices 202.

To reduce the amount of acoustic energy that is transmitted from the cooling plenum area 218 to the data storage areas 214A-H, an acoustic absorptive material 234 is positioned in the cooling plenum 220. When acoustic energy generated by the fan modules 222A-D is transmitted to and impacts the acoustic absorptive material 234, the acoustic absorptive material 234 attenuates the acoustic energy. As such, to the extent acoustic energy is reflected by the acoustic absorptive material 234, the magnitude of the reflected acoustic energy is significantly less (e.g., at least 50% lower) than the magnitude of the acoustic energy transmitted to the acoustic absorptive material 234. The acoustic absorptive material 234 can be made of non-metal materials such as porous polymer-based materials (e.g., polyurethane-based foam) and cloth fabrics. In certain embodiments, the acoustic absorptive material 234 reduces acoustic energy generated in a frequency range of 2,000 Hz and 50,000 Hz.

The acoustic absorptive material 234 can cover some, most, or all of the metal surfaces of the cooling plenum 220 positioned between the fan modules 222A-D and the data storage devices 202. In one example, some or all of the interior-facing surfaces of the bottom plenum wall 226A, the first side plenum wall 226B, the second side plenum wall 226C, the first top plenum wall 226D, the second top plenum wall 226E, and the back plenum wall 226F are covered by the acoustic absorptive material 234. In another example, only the bottom plenum wall 226A, the first top plenum wall 226D, and the second top plenum wall 226E are covered by the acoustic absorptive material 234. In another example, only the bottom plenum wall 226A and the first top plenum wall 226D are covered by the acoustic absorptive material 234.

In certain embodiments, the acoustic absorptive material 234 is not positioned or applied between the fan modules 222A-D and the metal surfaces of the plenum walls. For example, the acoustic absorptive material 234 may only be applied on the metal surfaces of the plenum walls within a gap between the data storage devices 202 and the fan modules 222A-D. The gap may extend along a longitudinal axis 236 of the drawer 202. As such, when the acoustic absorptive material 234 is not positioned between the fan modules 222A-D and the plenum walls, the fan modules 222A-D may rest directly on the metal surfaces of the plenum walls or directly on a chassis-vibration-dampening material 238 (e.g., an elastomer) that is positioned between the fan modules 222A-D and the metal surfaces of the plenum walls. This chassis-vibration-dampening material 238 helps reduce the amount of chassis vibration that is transmitted to the data storage devices 202 from the fan modules 222A-D via the chassis 204.

In certain embodiments, the acoustic absorptive material 234 is coupled to the metal surfaces of the plenum walls with an adhesive 240. In other embodiments, the acoustic absorptive material 234 is coupled to the plenum walls with mechanical fasteners (e.g., fasteners, clamps).

As shown in FIG. 5, some but not all acoustic energy generated by the fan modules 222A-D transmitted in a direction towards the acoustic absorptive material 234. For example, the acoustic energy represented by arrows 232A, 232C, and 232D is transmitted towards the acoustic absorptive material 234. This portion of the acoustic energy generated by the fan modules 222A-D will be attenuated by the acoustic absorptive material 234. However, the acoustic energy represented by the arrow 232B, which is aligned or which is parallel with the rotational axis 230 of the fan modules 222A-D, is transmitted directly towards the data storage devices 202. This portion of the acoustic energy generated by the fan modules 222A-D will not be attenuated by the acoustic absorptive material 234. As such, applying the acoustic absorptive material 234 to the plenum walls (e.g., around an internal perimeter of the cooling plenum 220) attenuates only part of the acoustic energy generated by the fan modules 222A-D. For example, some of the acoustic energy transmitted along directions oblique to the rotational axis 230 of the fan modules 222A-D will be attenuated by the acoustic absorptive material 234 while acoustic energy transmitted parallel to the rotational axis 230 (or perpendicular to faces of the fan modules 222A-D) will not be attenuated. However, because the acoustic absorptive material 234 does not block air generated by the fan modules 222A-D (unlike air baffles or flow straighteners), using the proposed acoustic absorptive material 234 has better cooling performance compared to using air baffles or flow straighteners. Put another way, use of the proposed acoustic absorptive material 234 allows a direct straight path for air to travel between the air movers 222A-D and the data storage devices 202. In certain embodiments, the acoustic absorptive material 234 is between 0.10 inches and 1 inches thick to allow sufficient air to travel from the fan modules 222A-D to the data storage devices 202.

FIG. 5 also shows power supply units 242 positioned in an area of the drawer 200 between the bottom wall 206E of the chassis 204 and the bottom plenum wall 226A of the cooling plenum 220. The power supply units 242 can be electrically coupled to one or more of the data storage devices 202 and/or the fan modules 222A-D.

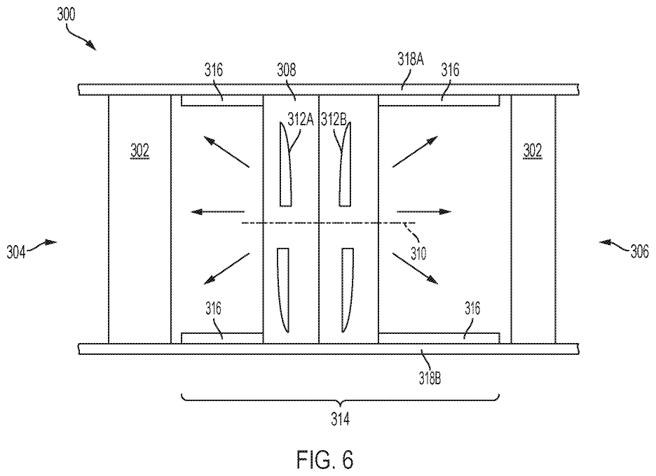

FIG. 6 shows a cross-sectional view of part of a drawer 300 with data storage devices 302 positioned at a front end 304 of the drawer 300 and at a back end 306 of the drawer 300. One or more fan modules 308 are positioned in the drawer 300 between the data storage devices 302. The fan modules 308 move air along a rotational axis 310 of the fan modules 308 via blades 312A, 312B.

The drawer 300 includes a cooling plenum 314 that directs air generated by the fan modules 308 towards the data storage devices 302. For example, air generated by the fan modules 308 travels through an internal space of the cooling plenum 314 before exiting the cooling plenum 314 and cooling the data storage devices 302. The cooling plenum 314 can be made of metal. As mentioned above, metal walls reflect acoustic energy such that little to no acoustic energy is absorbed when acoustic energy is transmitted to and reflected off the metal surfaces of the plenum walls. This results in most of the acoustic energy generated by the fan modules 308 being transmitted from the cooling plenum 314 to the data storage devices 302—thus reducing performance of the data storage devices 302.

An acoustic absorptive material 316 is positioned within the cooling plenum 314 such that some or all of the inward-facing metal surfaces of the cooling plenum are covered by the acoustic absorptive material 316. The acoustic absorptive material 316 reduces the amount of acoustic energy that is transmitted from the cooling plenum 314 to the data storage devices 302. The acoustic absorptive material 316 can comprise the same material(s) as the acoustic absorptive material described with respect to FIG. 5.

As shown above, covering some or all metal surfaces of the plenum walls helps reduce the amount of acoustic energy that is generated by fan modules and that impacts data storage devices positioned in drawers in data storage systems. Reducing the amount of acoustic energy that impacts the data storage devices improves the performance of the data storage devices. Although some acoustic energy is directed towards the data storage devices, the proposed use of the acoustic absorptive material to cover metal surfaces of the cooling plenum does not block or redirect as much cooling air compared to approaches that use baffles or flow straighteners. As such, the proposed approaches reduce the performance impact of acoustic energy on data storage devices while providing adequate cooling to the data storage devices.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

1. A system comprising:
a drawer including a chassis, the chassis including a data storage area and a cooling plenum, the cooling plenum including metal surfaces;
air movers positioned within the cooling plenum; and
an acoustic absorptive material covering at least a portion of the metal surfaces in the cooling plenum between the air movers and the data storage area to absorb acoustic energy that is generated by the air-movers and directed towards the data storage area.

2. The system of claim 1, wherein the acoustic absorptive material is positioned to reduce acoustic energy traveling to the data storage area.

3. The system of claim 1, wherein the drawer extends between a front end and a back end along a longitudinal axis, the system further comprising:
a gap between data storage devices positioned within the data storage area and the air movers along the longitudinal axis, wherein the acoustic absorptive material covers at least a portion of the metal surfaces in the gap.

4. The system of claim 3, wherein the data storage area is positioned at the front end of the drawer, wherein the cooling plenum is positioned at the back end of the drawer.

5. The system of claim 1, wherein the metal surfaces include a top metal surface, a bottom metal surface, first metal side surface, and a second metal side surface, wherein the acoustic absorptive material covers at least a portion of the top metal surface, the bottom metal surface, the first metal side surface, and the second metal side surface.

6. The system of claim 1, wherein the acoustic absorptive material is not positioned directly between the air movers and the metal surfaces of the cooling plenum.

7. The system of claim 1, wherein the air movers are fans with blades that rotate around a rotational axis, wherein the acoustic absorptive material is arranged to absorb acoustic energy transmitted along directions oblique to rotational axis.

8. The system of claim 7, wherein the acoustic absorptive material is arranged not to absorb acoustic energy transmitted along the rotational axis towards the data storage area.

9. The system of claim 1, wherein the acoustic absorptive material comprises a foam.

10. The system of claim 1, wherein the acoustic absorptive material is a non-metal material.

11. The system of claim 1, wherein the acoustic absorptive material reduces acoustic energy generated in a frequency range of 2,000 Hz and 50,000 Hz.

12. The system of claim 1, wherein the acoustic absorptive material is coupled to the top metal surface and the bottom metal surface with an adhesive.

13. The system of claim 1, wherein the air movers are coupled to the top metal surface or the bottom metal surface via vibration dampers different than the acoustic absorptive material.

14. The system of claim 1, wherein the acoustic absorptive material lines an internal perimeter of the cooling plenum.

15. The system of claim 1, wherein the acoustic absorptive materials are 0.10-1.0 inch thick.

16. A system comprising:
a drawer including a chassis, the chassis including data storage areas and a cooling plenum positioned between the data storage areas, the cooling plenum including metal surfaces;
fan modules positioned within the cooling plenum and that generate acoustic energy in opposite directions from each other and towards the date storage areas; and
an acoustic absorptive material covering at least a portion of the metal surfaces in the cooling plenum to reduce an amount of the acoustic energy generated by the fan modules from transporting to the data storage areas.

17. The system of claim 16, wherein the acoustic absorptive material is not positioned directly between the air movers and the metal surfaces of the cooling plenum.

18. The system of claim 16, wherein the acoustic absorptive material comprises a foam.

19. The system of claim 16, wherein the acoustic absorptive material is a non-metal material.

20. A method for attenuating acoustic energy generated by fan modules positioned in a cooling plenum of a drawer of a data storage system, the method comprising:
powering the fan modules to rotate blades around a rotational axis to generate acoustic energy;
absorbing at least some of the acoustic energy via an acoustic absorptive material covering metal surfaces of the cooling plenum between the fan modules and data storage devices positioned within the drawer; and
directing at least some of the acoustic energy to the data storage devices.
